(19) United States
(12) Patent Application Publication
(10) Pub. No.: US 2016/0134255 A1
(43) Pub. Date: May 12, 2016

(54) SURFACE ACOUSTIC WAVE DEVICE AND APPARATUS INCLUDING THE SAME

(71) Applicants: SAMSUNG ELECTRO-MECHANICS CO., LTD., Suwon-si (KR); CORECHIPS CO., LTD., Suwon-si (KR)

(72) Inventors: Hye Geun MIN, Suwon-si (KR); Jae Geun OH, Suwon-si (KR); Doo Hea KIM, Suwon-si (KR); Kwang Myung KIM, Suwon-si (KR); Jae Youn JEONG, Suwon-si (KR); Young Gu KANG, Suwon-si (KR); Jae Chan LEE, Suwon-si (KR)

(73) Assignees: CORECHIPS CO., LTD., Suwon-si (KR); SAMSUNG ELECTRO-MECHANICS CO., LTD., Suwon-si (KR)

(21) Appl. No.: 14/937,600

(22) Filed: Nov. 10, 2015

(30) Foreign Application Priority Data
Nov. 11, 2014 (KR) 10-2014-0156356

(51) Int. Cl. H03H 9/25; H03H 9/02

(52) U.S. Cl. CPC H03H 9/25; H03H 9/02543; H03H 9/02637

(57) ABSTRACT

A surface acoustic wave device includes: a piezoelectric substrate; an interdigital transducer disposed on the piezoelectric substrate, the interdigital transducer being configured to transduce a driving signal into a surface acoustic wave, and transduce a reflected surface acoustic wave into a response signal; a reflector arranged on the piezoelectric substrate and configured to reflect the surface acoustic wave input from the interdigital transducer; a first antenna disposed on the piezoelectric substrate, the first antenna extending radially from the interdigital transducer, and the first antenna being configured to receive the driving signal and transmit the response signal; and a second antenna disposed on the piezoelectric substrate, the second antenna extending radially from the interdigital transducer to be asymmetrical with respect to the first antenna, and the second antenna being configured to receive the driving signal and transmit the response signal.

### CROSS-REFERENCE TO RELATED APPLICATION(S)

This application claims the benefit of Korean Patent Application No. 10-2014-0156356 filed on Nov. 11, 2014 in the Korean Intellectual Property Office, the entire disclosure of which is incorporated herein by reference for all purposes.

### BACKGROUND

1. Field

The following description relates to a surface acoustic wave device and an apparatus including the same.

2. Description of Related Art

A surface acoustic wave (SAW) sensor is a sensor using characteristics of a surface acoustic wave device, and using a principle that frequency characteristics of a delay line of a surface acoustic wave generated while the surface acoustic wave travels along an electrode array of an interdigital transducer (IDT) on a piezoelectric substrate is physically and electrically changed.

In particular, by combining the surface acoustic wave sensor with wireless communications technology using a radio frequency, the surface acoustic wave sensor may be used as a powerless wireless sensor usable for difficult-to-access or measure structures or facilities by using an inter-transducing principle of an electromagnetic wave and an acoustic wave.

A driving principle of a wireless surface acoustic wave sensor will be briefly described. For example, when a driving signal generated by a controller is transmitted to an antenna of the surface acoustic wave device through an antenna of the controller, the signal is input to the interdigital transducer of the surface acoustic wave device and the piezoelectric substrate is vibrated by a radio frequency signal input to the interdigital transducer. As a result, the surface acoustic wave propagated along a surface of the piezoelectric substrate is generated to travel through the delay line and is propagated to a reflector.

The propagated surface acoustic wave described above is reflected by the reflector and is again transmitted by the antenna through the delay line and the interdigital transducer. Such a signal is received by the controller. Here, depending on changes in surrounding environments such as temperature, pressure, deformation, and the like around the piezoelectric substrate, the delay line is expanded or contracted and a property of the piezoelectric substrate is also influenced thereby. Thus, a propagation time of the surface acoustic wave is changed or a resonance frequency of the surface acoustic wave is changed. Therefore, by detecting the changes in the above-mentioned characteristics, a desired physical quantity may be measured.

The surface acoustic wave sensor as described above may include the surface acoustic wave device and the controller. In addition, the surface acoustic wave sensor may be classified into a wired surface acoustic wave sensor and a wireless surface acoustic wave sensor depending on whether or not a transmission line is present between the surface acoustic wave device and the controller.

The wired surface acoustic wave sensor includes the surface acoustic wave device and the controller. The surface acoustic wave device and the controller are simply connected to each other by the transmission line. Conversely, the wireless surface acoustic wave sensor does not have the transmission line between the surface acoustic wave device and the controller, and transmits the signal as the electromagnetic wave using a radio frequency antenna instead of the transmission line.

The radio frequency antenna is connected to the controller and is also included in the surface acoustic wave device.

For instance, the surface acoustic wave device may include the antenna in addition to the interdigital transducer, the reflectors, and a piezoelectric single crystal, to wirelessly receive the signal from the controller.

The surface acoustic wave device of the wireless surface acoustic wave sensor as described above is packaged and used to prevent physical damage of the interdigital transducer and the reflectors, protect the interdigital transducer and the reflectors from contamination such as dust, moisture, or the like, and facilitate a coupling with the antenna.

A representative example of a packaging method includes housing the surface acoustic wave device in a surface-mount device (SMD) or mounting the surface acoustic wave device on a printed circuit board.

The surface acoustic wave device is externally connected by first attaching the surface acoustic wave device to the surface-mount device or the printed circuit board by an epoxy, connecting the interdigital transducer and the electrode array of the surface acoustic wave device by a wire-bonding method, and then attaching the antenna to the electrode array by a soldering, brazing, or welding method.

However, the bond, the epoxy, the solder, and the like used to package the surface acoustic wave device having the form as described above are vulnerable to extreme environments such as high temperatures, or the like. Thus, the bond, the epoxy, the solder, and the like may be easily detached and cause impedance loss according to a heterogeneous coupling and a wire length from the interdigital transducer to the antenna.

### SUMMARY

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

According to one general aspect, a surface acoustic wave device includes: a piezoelectric substrate; an interdigital transducer disposed on the piezoelectric substrate, the interdigital transducer being configured to transduce a driving signal into a surface acoustic wave, and transduce a reflected surface acoustic wave into a response signal; a reflector arranged on the piezoelectric substrate and configured to reflect the surface acoustic wave input from the interdigital transducer; a first antenna disposed on the piezoelectric substrate, the first antenna extending radially from the interdigital transducer, and the first antenna being configured to receive the driving signal and transmit the response signal; and a second antenna disposed on the piezoelectric substrate, the second antenna extending radially from the interdigital transducer to be asymmetrical with respect to the first antenna, and the second antenna being configured to receive the driving signal and transmit the response signal.

The piezoelectric substrate may include, as a main component, at least one of zinc oxide, aluminum nitride, lithium tantalate, lithium niobate, potassium niobate, lanthanum gallium silicate, or quartz.

The first antenna may include a first bent portion of a meander shape formed on an end portion of the first antenna, and the second antenna may include a second bent portion of a meander shape formed on an end portion of the second antenna.

A line interval of each of the first bent portion and the second bent portion may be at least 1.5 times greater than a line width of each of the first bent portion and the second bent portion.

The reflector may include a first sub-reflector and a second sub-reflector, and the first sub-reflector and the second sub-reflector may be arranged on the substrate on opposite sides of the interdigital transducer.

A length of each of the first antenna and the second antenna may be matched to ¼ of an antenna wavelength.

According to another general aspect, an apparatus includes: a plate-shaped lower end part having a predetermined thickness and including a mounting recess formed in a surface of the lower end part; a surface acoustic wave device mounted in the mounting recess; an upper end part configured to cover the lower end part; and a fastening part coupling the lower end part to the upper end part.

The apparatus may further include a metal plate coupled to the lower end part.

The upper end part may include slots disposed on opposite sides of the upper end part, and the lower end part may be received in the slots to be coupled to the upper end part.

The upper end part may include fastening grooves provided on opposite sides of the upper end part, and the fastening part may include: a finishing member including an insertion groove configured to receive the lower end part, and through-holes disposed in opposite sides of the finishing member; and fastening units fastened to the fastening grooves through the through-holes to couple the lower end part to the upper end part.

The lower end part may include fastening grooves disposed along a periphery of the mounting recess, the upper end part may include through-holes disposed to correspond to the plurality of fastening grooves, and the fastening part may couple the lower end part to the upper end part by fixing units passing through the through-holes corresponding thereto to be coupled to the fastening grooves.

The surface acoustic wave device may include: a piezoelectric substrate; an interdigital transducer disposed on the piezoelectric substrate, the interdigital transducer being configured to transduce a driving signal into a surface acoustic wave, and transduce a reflected surface acoustic wave into a response signal; a reflector arranged on the piezoelectric substrate and configured to reflect the surface acoustic wave input from the interdigital transducer; a first antenna disposed on the piezoelectric substrate, the first antenna extending radially from the interdigital transducer, and the first antenna being configured to receive the driving signal and transmit the response signal; and a second antenna disposed on the piezoelectric substrate, the second antenna extending radially from the interdigital transducer to be asymmetrical with respect to the first antenna, and the second antenna being configured to receive the driving signal and transmit the response signal.

The upper end part may include a fixing part that protrudes downwardly from a lower surface of the upper end part to space the interdigital transducer and the reflector from the upper end part by a predetermined space.

The apparatus may further include: an antenna apparatus configured to transmit a driving signal to the surface acoustic wave device and receive a response signal from the surface acoustic wave device; and a controller configured to transmit the driving signal to the surface acoustic wave device via the antenna apparatus and receive the response signal via the antenna apparatus.

The upper end part may include a fixing part that protrudes downwardly from a lower surface of the upper end part to space the surface acoustic wave device from the upper end part by a predetermined space.

Other features and aspects will be apparent from the following detailed description, the drawings, and the claims.

### BRIEF DESCRIPTION OF DRAWINGS

FIG. 1 is a view of a surface acoustic wave device according to an example.

FIG. 2 is a view illustrating an example of an interdigital transducer and a reflector of FIG.

FIG. 3 is a graph illustrating a frequency measured according to a temperature change after the surface acoustic wave device of FIG. 1 is inserted into a box oven.

FIG. 4 is an exploded perspective view of a mounting apparatus for a surface acoustic wave device according to an example.

FIG. 5 is an assembly view of the mounting apparatus for a surface acoustic wave device according to an example.

FIG. 6 is an exploded perspective view of a mounting apparatus for a surface acoustic wave device according to another example.

FIG. 7 is an assembly view of the mounting apparatus for a surface acoustic wave device according to another example.

FIG. 8 is a schematic diagram of a measurement sensor using the mounting apparatus for a surface acoustic wave device according to an example.

Throughout the drawings and the detailed description, the same reference numerals refer to the same elements. The drawings may not be to scale, and the relative size, proportions, and depiction of elements in the drawings may be exaggerated for clarity, illustration, and convenience.

### DETAILED DESCRIPTION

The following detailed description is provided to assist the reader in gaining a comprehensive understanding of the methods, apparatuses, and/or systems described herein. However, various changes, modifications, and equivalents of the methods, apparatuses, and/or systems described herein will be apparent to one of ordinary skill in the art. The sequences of operations described herein are merely examples, and are not limited to those set forth herein, but may be changed as will be apparent to one of ordinary skill in the art, with the exception of operations necessarily occurring in a certain order. Also, descriptions of functions and constructions that are well known to one of ordinary skill in the art may be omitted for increased clarity and conciseness.

The features described herein may be embodied in different forms, and are not to be construed as being limited to the examples described herein. Rather, the examples described herein have been provided so that this disclosure will be thorough and complete, and will convey the full scope of the disclosure to one of ordinary skill in the art.

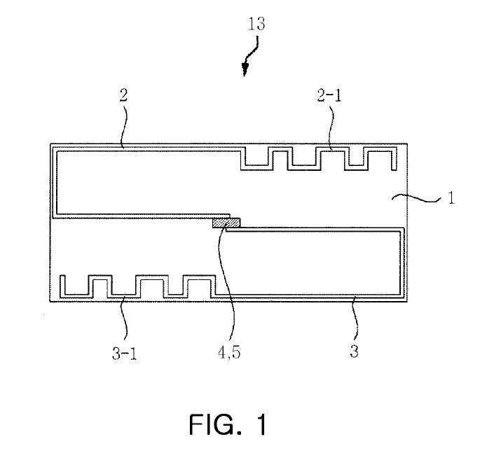

FIG. 1 is a view of a surface acoustic wave device 13 according to an embodiment.

Referring to FIG. 1, the surface acoustic wave device 13 includes a piezoelectric substrate 1, a first antenna 2, a second antenna 3, an interdigital transducer 4, and a reflector 5.

The piezoelectric substrate 1 is formed in a thin plate shape and is vibrated when a radio frequency signal is applied thereto. The piezoelectric substrate 1 may be formed from a material including at least one of zinc oxide, aluminum nitride, lithium tantalate, lithium niobate, potassium niobate, lanthanum gallium silicate, and quartz as a main material. By forming the piezoelectric substrate 1 using the above-mentioned material, the surface acoustic wave device 13 may have a high frequency and good temperature characteristics.

The first antenna 2 is formed on a surface of the piezoelectric substrate 1, extends radially from the interdigital transducer 4 and the reflector 5 placed around the center of the piezoelectric substrate 1 while having a length suitable for a resonance frequency, and is disposed in a spatially-efficient bent shape. The second antenna 3 is also formed on the surface of the piezoelectric substrate 1, extends radially from the interdigital transducer 4 and the reflector 5 while having a length suitable for the resonance frequency, and is disposed in a spatially-efficient bent shape. The first antenna 2 and the second antenna 3 may be asymmetrically formed to generally form a meander shape on the piezoelectric substrate 1.

The first antenna 2 and the second antenna 3 form a dipole antenna and may be formed to have lengths suitable for the resonance frequency. In a case in which the piezoelectric substrate 1 has a high dielectric constant, the lengths of the first antenna 2 and the second antenna 3 may be reduced, and in a case in which the first antenna 2 and the second antenna 3 are bent several times, a surface area occupied by the first antenna 2 and the second antenna 3 may be reduced. For instance, in a case in which end portions of the first antenna 2 and the second antenna 3 have first and second bent portions 2-1 and 3-1, respectively, desired performance may be implemented while reducing the surface area occupied by the first antenna 2 and the second antenna 3.

In a case in which the first and second bent portions 2-1 and 3-1 of the first antenna 2 and the second antenna 3 are too complicatedly twisted, lines which are adjacent to each other may allow current to flow in different directions, and thus inductances may be offset. Therefore, when a line interval of each of the first and second bent portions 2-1 and 3-1 of the first antenna 2 and the second antenna 3 is 1.5 times greater or more than a line width thereof, an influence of mutual-inductance may be significantly reduced.

The first antenna 2 and the second antenna 3 may be formed, for example, of aluminum, and may be formed by performing a printing on the piezoelectric substrate 1 by a lithography method.

The length L of each of the first antenna 2 and the second antenna 3 may be formed to be matched to ¼ of an antenna wavelength λₐₙₜ.

L=λₐₙₜ/4 [Equation 1]

The antenna wavelength λₐₙₜ is calculated from an effective dielectric constant ∈_{eff}, and the effective dielectric constant ∈_{eff} is determined by a relative dielectric constant ∈ᵣ, a thickness h of the piezoelectric substrate 1, and an antenna line width W.

Λₐₙₜ=λₐᵢᵣ/∈_{eff}^{1/2}, λₐᵢᵣ=c/f [Equation 2]

∈_{eff}=(∈ᵣ+i)/2+(∈ᵣ−1)/2·1/(1+12h/W)^{1/2} [Equation 3]

Where λₐᵢᵣ indicates a dielectric constant of air.

From Equations 1 to 3, a length (λₐₙₜ/4) of the first antenna 2 or the second antenna 3 (∈ᵣ>1) may be shorter than a length (λₐᵢᵣ/4) of an antenna in the air, for example, an antenna exposed to air.

The length of the first antenna 2 and the second antenna 3 described above is calculated by a frequency f, the thickness h of the piezoelectric substrate, the antenna line width W, and the relative dielectric constant ∈ᵣ, which are illustrated in Table 1.

TABLE 1

| | Lithium Niobate | Quartz |
|---|---|---|
| ∈ᵣ | 4.39 | 4.5 |
| h (mm) | 0.5 | 0.5 |
| W (mm) | 1.3 | 1.3 |
| ∈_{eff} | 3.3 | 3.4 |
| f (MHz) | 430 | 430 |
| λₐᵢᵣ (mm) | 698 | 698 |
| λₐₙₜ (mm) | 378 | 374 |
| L (mm) | 94 | 93 |

The length of each of the first antenna 2 and the third antenna 3 may be calculated as 94 mm in a case in which the piezoelectric substrate 1 is lithium niobate, and may be calculated as 93 mm in a case in which the piezoelectric substrate 1 is quartz.

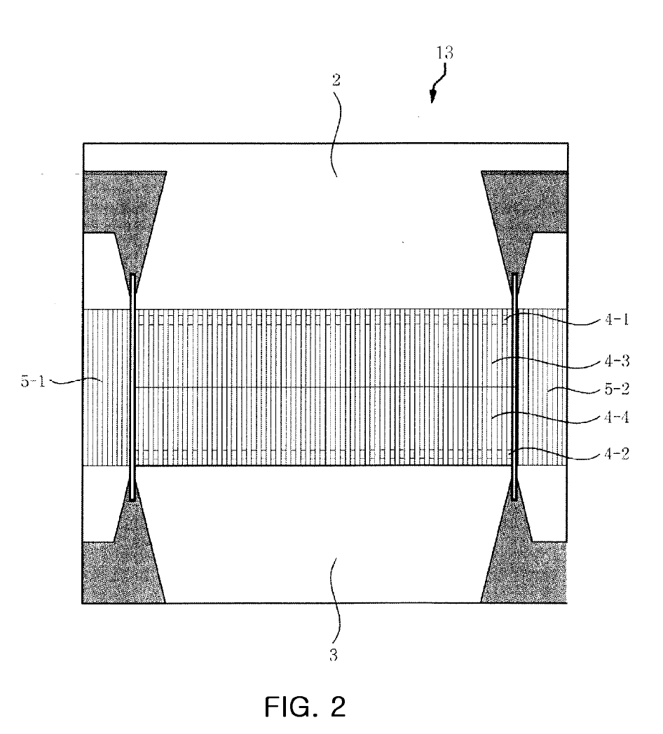

The interdigital transducer 4 is formed on a surface of the piezoelectric substrate 1, and transduces a driving signal into a surface acoustic wave and transduces a reflected surface acoustic wave into a response signal. The interdigital transducer 4 has a positive terminal 4-1 and a negative terminal 4-2 as illustrated in FIG. 2. In addition, a comb-shaped positive electrode array 4-3 is connected to the positive terminal, and a comb-shaped negative electrode array 4-4 may also be connected to the negative terminal 4-2. The comb-shaped positive electrode array 4-3 and the comb-shaped negative electrode array 4-4 face each other and are engaged with each other. The first antenna 2 is connected to the positive terminal 4-1 and the second antenna 3 is connected to the negative terminal 4-2.

In addition, the reflector 5 is arranged on the surface of the piezoelectric substrate 1, adjacent to the interdigital transducer 4, and reflects the surface acoustic wave input from the interdigital transducer 4. As illustrated in FIG. 2, the reflector 5 includes a first sub-reflector 5-1 and a second sub-reflector 5-2, which are positioned on opposite sides of the interdigital transducer 4. The first sub-reflector 5-1 and the second sub-reflector 5-2 each include a plurality of reflecting bodies arranged to be parallel to each other at a predetermined interval, and each generally form a comb-shaped structure. In this manner, the respective sub-reflectors 5-1 and 5-2 may reflect the surface acoustic wave at a high frequency.

By adjusting widths, intervals, thicknesses, and the like of the electrode array of the interdigital transducer 4 and the reflecting body of the reflector 5, an oscillating frequency of the surface acoustic wave may be set to a desired value.

The configurations of the respective sub-reflectors 5-1 and 5-2 may be the same, or they may be different from each other. In a case in which sub-reflectors 5-1 and 5-2 have substantially the same configuration, the surface acoustic wave may be more definitely limited between the sub-reflectors 5-1 and 5-2. As a result, a stronger surface acoustic wave may be formed.

Examples of a material forming the interdigital transducer 4 and the reflector 5 include aluminum (Al), copper (Cu), tungsten (W), molybdenum (Mo), titanium (Ti), gold (Au), tantalum (Ta), nickel (Ni), chromium (Cr), germanium (Ge), platinum (Pt), and the like, and alloys thereof. One or more of these materials may be combined to be used.

The surface acoustic wave device 13 manufactured as described above wirelessly transmits and receives a frequency signal to and from a controller. For instance, in a case in which the first antenna 2 and the second antenna 3 receive a driving signal generated by the controller, the driving signal is input to the interdigital transducer 4 of the surface acoustic wave device 13. In addition, the piezoelectric substrate 1 is vibrated by a radio frequency signal input to the interdigital transducer 4. As a result, a surface acoustic wave propagated along the surface of the piezoelectric substrate 1 is generated to travel through the electrode array and is propagated to the reflector 5.

The surface acoustic wave propagated as described above is reflected by the reflector 5 and transduced into the response signal through the electrode array and the interdigital transducer 4 to be transmitted by the first antenna 2 and the second antenna 3. This signal is received by the controller.

Depending on changes in surrounding environments such as temperature, pressure, deformation, and the like around the piezoelectric substrate 1, the electrode array is expanded or contracted, and a property of the piezoelectric substrate 1 is also influenced thereby, and thus a propagation time or a reference frequency of the surface acoustic wave is changed. Therefore, the controller detects the changes in the above-mentioned characteristics, and thus a desired physical quantity may be measured.

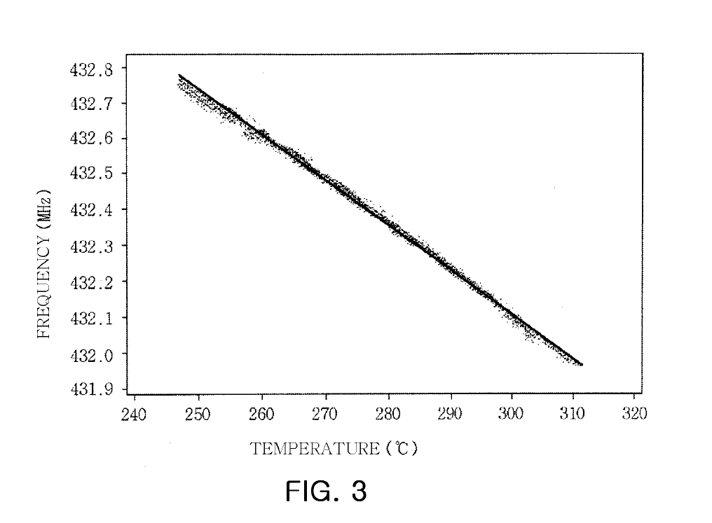

FIG. 3 is a graph illustrating a frequency measured according to a temperature change after the surface acoustic wave device 13 is inserted into a box oven, wherein it was confirmed that the first antenna 2 and the second antenna 3 are operated in a frequency band of 430 MHz. In particular, a frequency change in a temperature range of 250° C. to 310° C. exhibits linearity.

In general, most high temperature heating equipment such as a hot plate or a box oven are formed of a metal, and a location on which the surface acoustic wave device 13 is placed may be a metal shelf or a metal bottom. In a case in which the first antenna 2 and the second antenna 3 are too close to the metal shelf or the metal bottom, radiation efficiency of the antenna may be rapidly degraded, since the metal absorbs all electromagnetic waves. Therefore, there is a need for a mounting apparatus for preventing physical damage of the interdigital transducer 4 and the reflector 5, preventing contamination from dust, moisture, and the like, and spacing the surface acoustic wave device 13 from the metal shelf or the metal bottom.

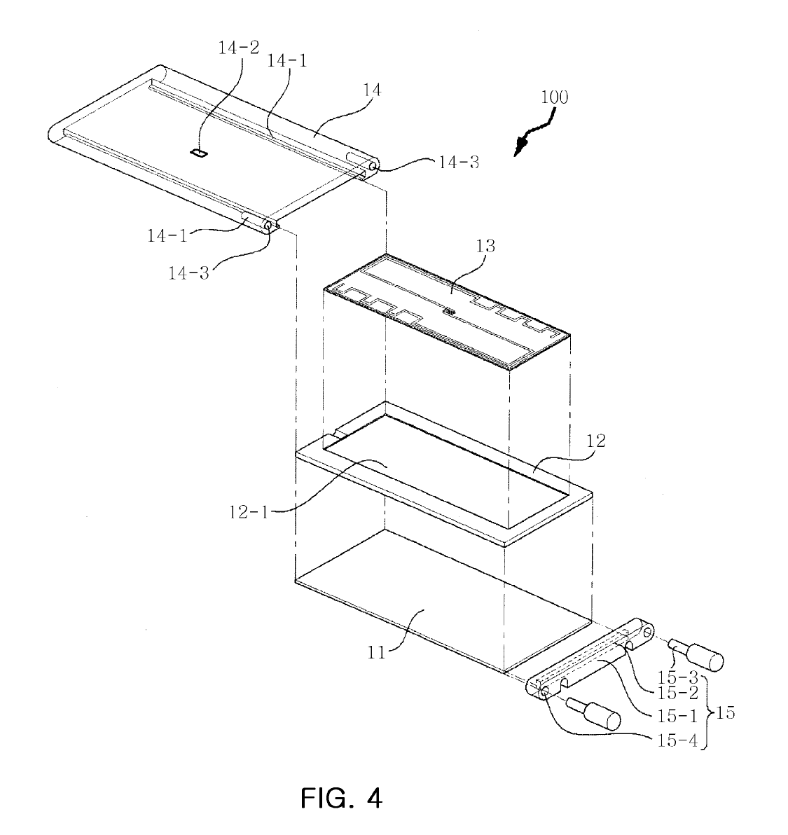

FIG. 4 is an exploded perspective view of a mounting apparatus for a surface acoustic wave device 100 according to an embodiment.

Referring to FIG. 4, the mounting apparatus for a surface acoustic wave device 100 includes a metal plate 11, a lower end part 12, the surface acoustic wave device 13, an upper end part 14, and a fastening part 15.

The metal plate 11 is a plate-shaped member having a predetermined thickness, and is attached to a lower portion of the lower end part 12 to maintain a predetermined distance between the surface acoustic wave device 13 and a surface of the metal plate 11. The metal plate 11 is attached to the lower end part 12 by a fixing unit such as a fastening screw, or the like, or may be coated with a thin film, or the like, to be secured to the lower end part 12.

In addition, the lower end part 12 is a plate-shaped member including a mounting recess 12-1 in which the surface acoustic wave device 13 is mounted and fixed.

The upper end part 14 is formed in a plate shape, and includes slots 14-1 formed on opposite sides thereof so that the lower end part 12 can be coupled and fixed to the surface acoustic wave device 13 in a sliding manner.

The upper end part 14 includes a fixing part 14-2 that protrudes downwardly from a lower surface of the upper end part 14 at the central portion of the upper end part 14 to allow the interdigital transducer 4 and the reflector 5 of the surface acoustic wave device 13 to be spaced apart from the upper end part 14 when the lower end part 12, in which the surface acoustic wave device 13 is mounted, is coupled to the upper end part 14. Thus the interdigital transducer 4 and the reflector 5 are prevented from contacting the upper end part 14 in the mounting apparatus 100.

The upper end part 14 includes a pair of fastening grooves 14-3 formed at entrance portions of the slots 14-1 of opposite sides of the upper end part 14, and fastening units 15-3, such as fastening screws, included in the fastening part 15 are fastened to the fastening grooves 14-3, thereby fixing the lower end part 12.

The fastening part 15 includes a finishing member 15-1 into which the lower end part 12 is inserted to be fixed to the fastening part 15. Specifically, the finishing member 15-1 includes an insertion groove 15-2 formed in one surface thereof, and the lower end part 12 is inserted into the insertion groove 15-2 to be fixed to the fastening part 15. In addition, the finishing member 15-1 includes through-holes 15-4 in opposite sides thereof, and the fastening units 15-3 penetrate through the through-holes 15-4. The fastening units 15-3 are fastened to the fastening grooves 14-3 through the through-holes 15-4, and thus the lower end part 12 is firmly fixed to the upper end part 14.

The mounting apparatus 100 may selectively include the metal plate 11. That is, the metal plate 11 may be omitted.

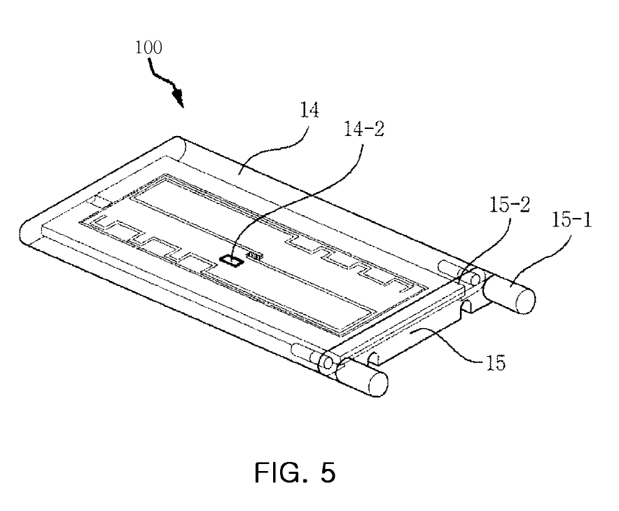

FIG. 5 illustrates a form in which the lower end part 12 is fastened to the upper end part 14.

The mounting apparatus 100 as described above includes the metal plate 11 in addition to the lower end part 12 having the predetermined thickness, and thus the surface acoustic wave device 13 is less influenced by an environment of the mounting apparatus 100.

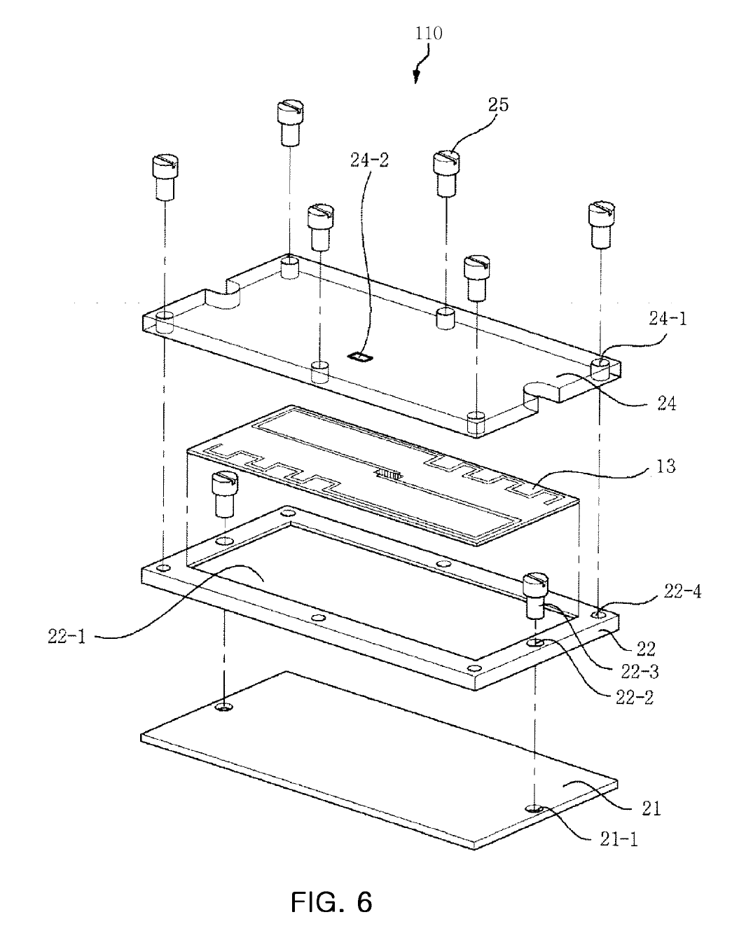

FIG. 6 is an exploded perspective view of a mounting apparatus for a surface acoustic wave device 110 according to another embodiment.

Referring to FIG. 6, the mounting apparatus for a surface acoustic wave device 110 according to another embodiment includes a metal plate 21, a lower end part 22, the surface acoustic wave device 13, an upper end part 24, and a fastening part 25.

The metal plate 21 is plate-shaped and has a predetermined thickness, and is attached to a lower portion of the lower end part 22 to maintain a predetermined distance between the surface acoustic wave device 13 and a lower surface of the metal plate 21. The metal plate 21 includes a pair of fastening grooves or holes 21-1 formed in opposite ends thereof so that the metal plate 21 can be coupled to the lower end part 22.

The lower end part 22 is plate-shaped and includes a mounting recess 22-1 in which the surface acoustic wave device 13 is mounted and fixed. The lower end part 22 includes through-holes 22-2 formed in opposite sides thereof so that the metal plate 21 may be fixed to the lower portion of the lower end part 22 using fixing units 22-3, such as fastening screws, or the like. The fixing units 22-3 are coupled to the fastening grooves 21-1 of the metal plate 21 through the through-holes 22-2 of the lower end part 22, thereby firmly coupling the metal plate 21 to the lower end part 22. In addition, the lower end part 22 includes a plurality of fastening grooves 22-4 formed along a periphery thereof so that the lower end part 22 may be coupled to a lower surface of the upper end part 24.

The upper end part 24 is formed in a plate shape and includes a plurality of through-holes 24-1 formed along a periphery thereof. The fastening part 25 includes fixing units such as a plurality of fastening screws, and the like, and the fixing units are fastened to the corresponding fastening grooves 22-4 of the lower end part 22 through the through-holes 24-1, thereby firmly fixing the lower end part 22 to the upper end part 24.

The upper end part 24 includes a fixing part 24-2 that protrudes downwardly from a lower surface of the upper end part 24 to allow the interdigital transducer 4 and the reflector 5 of the surface acoustic wave device 13 to be spaced apart from the upper end part 24 by a predetermined space when the lower end part 22, in which the surface acoustic wave device 13 is mounted, is coupled to the upper end part 24.

The mounting apparatus 110 as described above may selectively include the metal plate 21. That is, the metal plate 21 may be omitted.

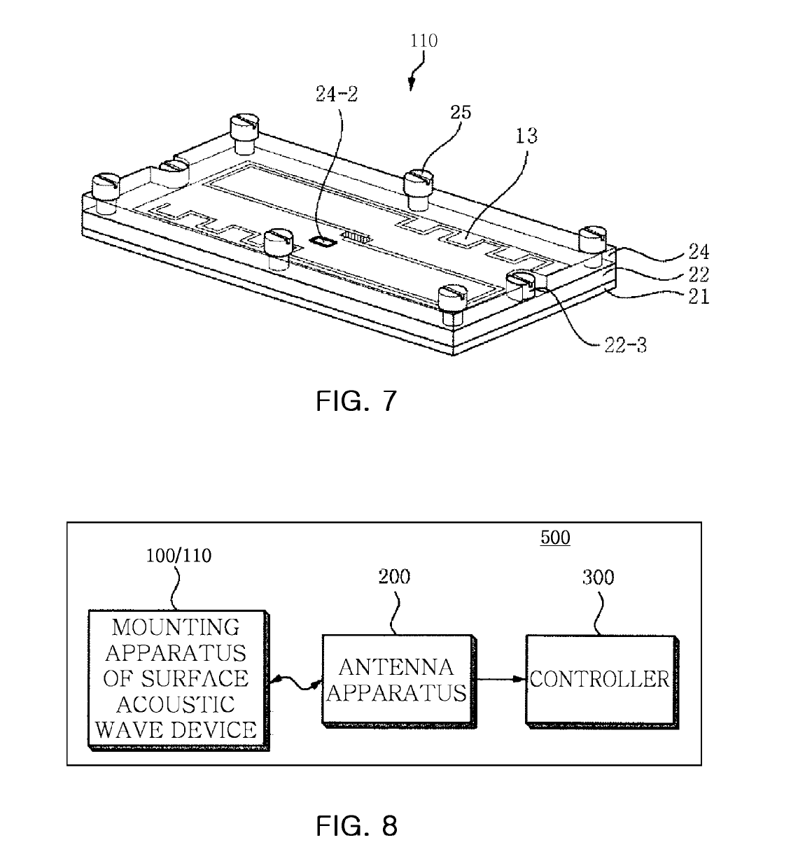

FIG. 7 illustrates a form in which the lower end part 22 is fastened to the upper end part 24.

In addition, the mounting apparatus 110 includes the metal plate 21 in addition to the lower end part 22 having the predetermined thickness, and thus the surface acoustic wave device 13 is less influenced by an environment of the mounting apparatus 110.

FIG. 8 is a schematic diagram of a measurement sensor 500 including the mounting apparatus 100/110.

Referring to FIG. 8, the measurement sensor 500 includes the mounting apparatus 100/110, an antenna apparatus 200, and a controller 300.

The surface acoustic wave device 13 included in the mounting apparatus 100/110 is influenced by a change in a surrounding environment such as temperature, pressure, deformation, or the like around the surface acoustic wave device 13, and thus a propagation time or a resonance frequency of the surface acoustic wave may be changed, and the controller 300 may detect the change in the above-mention characteristics, and thus a desired physical quantity may be measured.

In a case in which the mounting apparatus 100/110 receives a driving signal from the controller 300 through the antenna apparatus 200, the surface acoustic wave device 13 detects ambient temperature, pressure, torque, vibration, gas, or mass and outputs a radio frequency signal corresponding to the detected ambient temperature, pressure, torque, vibration, gas, or mass.

In addition, the antenna apparatus 200 receives the driving signal from the controller 300 to transmit the driving signal to the surface acoustic wave device 13 and receives a radio frequency signal from the surface acoustic wave device 13 to transmit the radio frequency signal to the controller 300. Here, the mounting apparatus 100/110 may be installed in a target object of which temperature is to be detected, and the target object may be, for example, a high temperature apparatus such as a semiconductor cure oven.

The controller 300 transmits the driving signal to the surface acoustic wave device 13 and receives the radio frequency signal from the surface acoustic wave device 13 through the antenna apparatus 200, and calculates a physical quantity corresponding to the radio frequency signal. Here, the controller 300 may be connected to the antenna apparatus 200 through a wired line such as a coaxial cable.

The measurement sensor 500 may be installed in an environment of a higher temperature (up to 1000° C.). For instance, specifically, the measurement sensor 500 may measure physical quantities such as pressure, deformation, torque, temperature, vibration, gas, mass, and the like in an extreme environment.

While this disclosure includes specific examples, it will be apparent to one of ordinary skill in the art that various changes in form and details may be made in these examples without departing from the spirit and scope of the claims and their equivalents. The examples described herein are to be considered in a descriptive sense only, and not for purposes of limitation. Descriptions of features or aspects in each example are to be considered as being applicable to similar features or aspects in other examples. Suitable results may be achieved if the described techniques are performed in a different order, and/or if components in a described system, architecture, device, or circuit are combined in a different manner, and/or replaced or supplemented by other components or their equivalents. Therefore, the scope of the disclosure is defined not by the detailed description, but by the claims and their equivalents, and all variations within the scope of the claims and their equivalents are to be construed as being included in the disclosure.

What is claimed is:

1. A surface acoustic wave device comprising:
a piezoelectric substrate;
an interdigital transducer disposed on the piezoelectric substrate, the interdigital transducer being configured to transduce a driving signal into a surface acoustic wave, and transduce a reflected surface acoustic wave into a response signal;
a reflector arranged on the piezoelectric substrate and configured to reflect the surface acoustic wave input from the interdigital transducer;
a first antenna disposed on the piezoelectric substrate, the first antenna extending radially from the interdigital transducer, and the first antenna being configured to receive the driving signal and transmit the response signal; and
a second antenna disposed on the piezoelectric substrate, the second antenna extending radially from the interdigital transducer to be asymmetrical with respect to the first antenna, and the second antenna being configured to receive the driving signal and transmit the response signal.

2. The surface acoustic wave device of claim 1, wherein the piezoelectric substrate comprises, as a main component, at least one of zinc oxide, aluminum nitride, lithium tantalate, lithium niobate, potassium niobate, lanthanum gallium silicate, or quartz.

3. The surface acoustic wave device of claim 1, wherein the first antenna comprises a first bent portion of a meander shape formed on an end portion of the first antenna, and wherein the second antenna comprises a second bent portion of a meander shape formed on an end portion of the second antenna.

4. The surface acoustic wave device of claim 1, wherein a line interval of each of the first bent portion and the second bent portion is at least 1.5 times greater than a line width of each of the first bent portion and the second bent portion.

5. The surface acoustic wave device of claim 1, wherein the reflector comprises a first sub-reflector and a second sub-reflector, and the first sub-reflector and the second sub-reflector are arranged on the substrate on opposite sides of the interdigital transducer.

6. The surface acoustic wave device of claim 1, wherein a length of each of the first antenna and the second antenna is matched to ¼ of an antenna wavelength.

7. An apparatus comprising:
a plate-shaped lower end part having a predetermined thickness and comprising a mounting recess formed in a surface of the lower end part;
a surface acoustic wave device mounted in the mounting recess;
an upper end part configured to cover the lower end part; and
a fastening part coupling the lower end part to the upper end part.

8. The apparatus of claim 7, further comprising a metal plate coupled to the lower end part.

9. The apparatus of claim 7, wherein the upper end part comprises slots disposed on opposite sides of the upper end part, and wherein the lower end part is received in the slots to be coupled to the upper end part.

10. The apparatus of claim 9, wherein the upper end part comprises fastening grooves provided on opposite sides of the upper end part, and wherein the fastening part comprises:
a finishing member comprising an insertion groove configured to receive the lower end part, and through-holes disposed in opposite sides of the finishing member; and
fastening units fastened to the fastening grooves through the through-holes to couple the lower end part to the upper end part.

11. The apparatus of claim 7, wherein:
the lower end part comprises fastening grooves disposed along a periphery of the mounting recess,
the upper end part comprises through-holes disposed to correspond to the plurality of fastening grooves, and
the fastening part couples the lower end part to the upper end part by fixing units passing through the through-holes corresponding thereto to be coupled to the fastening grooves.

12. The apparatus of claim 7, wherein the surface acoustic wave device comprises:
a piezoelectric substrate;
an interdigital transducer disposed on the piezoelectric substrate, the interdigital transducer being configured to transduce a driving signal into a surface acoustic wave, and transduce a reflected surface acoustic wave into a response signal;
a reflector arranged on the piezoelectric substrate and configured to reflect the surface acoustic wave input from the interdigital transducer;
a first antenna disposed on the piezoelectric substrate, the first antenna extending radially from the interdigital transducer, and the first antenna being configured to receive the driving signal and transmit the response signal; and
a second antenna disposed on the piezoelectric substrate, the second antenna extending radially from the interdigital transducer to be asymmetrical with respect to the first antenna, and the second antenna being configured to receive the driving signal, and transmit the response signal.

13. The apparatus of claim 12, wherein the upper end part comprises a fixing part that protrudes downwardly from a lower surface of the upper end part to space the interdigital transducer and the reflector from the upper end part by a predetermined space.

14. The apparatus of claim 7, further comprising:
an antenna apparatus configured to transmit a driving signal to the surface acoustic wave device and receive a response signal from the surface acoustic wave device; and
a controller configured to transmit the driving signal to the surface acoustic wave device via the antenna apparatus and receive the response signal via the antenna apparatus.

15. The apparatus of claim 7, wherein the upper end part comprises a fixing part that protrudes downwardly from a lower surface of the upper end part to space the surface acoustic wave device from the upper end part by a predetermined space.
